(19) United States
(12) Patent Application Publication
(10) Pub. No.: US 2011/0233731 A1
(43) Pub. Date: Sep. 29, 2011

(54) SEMICONDUCTOR DEVICE AND METHOD OF PRODUCING THE SAME

(75) Inventor: Shinya Yamazaki, Aichi-ken (JP)

(73) Assignee: TOYOTA JIDOSHA KABUSHIKI KAISHA, Toyota-shi (JP)

(21) Appl. No.: 13/128,385

(22) PCT Filed: Nov. 9, 2009
(86) PCT No.: PCT/IB09/07367

§ 371 Date: Jun. 9, 2011

(30) Foreign Application Priority Data
Nov. 10, 2008 (JP) 2008-287803

(51) Int. Cl. H01L 29/32; H01L 21/265

(52) U.S. Cl. 257/617; 438/530; 257/E21.334; 257/E29.107

(57) ABSTRACT

A semiconductor device, in which a plurality of crystal defects for controlling the life time of carries are distributed in a silicon substrate, is characterized in that the total number of the crystal defects that cause a trap level that differs from the energy level of the center of the band gap by less than 0.2 eV, is less than the number of the crystal defects that cause the trap level that is the closest to the energy level of the center of the band gap among trap levels that differ from the energy level of the center of the band gap by 0.2 eV or more.

### BACKGROUND OF THE INVENTION

1. Field of the Invention

The invention relates to a semiconductor device and a method of producing the semiconductor device, and in particular, to a semiconductor device, in which a plurality of crystal defects for controlling the life time of carriers are formed in the silicon substrate.

2. Description of the Related Art

A technology for controlling the life time of carriers in a silicon substrate by forming crystal defects in the silicon substrate during the process of producing the semiconductor device, is available. In this technology, a plurality of trap levels are distributed within the band gap in the silicon substrate by forming crystal defects in the silicon substrate. The carriers are captured by the plurality of trap levels, so that the recombination of carriers is promoted and the life time of carriers is reduced. The crystal defects herein mean what cause the irregularity of the crystal structure of a silicon substrate and therefore mean not only the lattice defects (vacancies: lack of part of silicon atoms, interstitial silicon: silicon atoms out of the lattice points) but also impurity atoms, and the combinations and/or the aggregation of the impurity atoms and the lattice defects. Thus, the crystal defects that cause the deep trap level described later in this specification are the portions, at each of which the silicon atom is missing that is an element of the crystal structure of the silicon substrate.

The technology for forming crystal defects in a silicon substrate generally employs irradiation of the silicon substrate with particle rays, such as helium ions. In this way, it is possible to form the crystal defects in the silicon substrate with favorable controllability and it is therefore possible to obtain a favorable function of controlling the life time of carriers. Examples of such a related art include one that is described in Japanese Patent Application Publication No. 5-102161 (JP-A-5-102161).

However, when the total number of crystal defects in a silicon substrate increases, application of a reverse direction voltage to the semiconductor device causes the crystal defects to generate carriers, so that the leakage current increases. On the other hand, when the total number of crystal defects formed in the silicon substrate is reduced to reduce the leakage current, the frequency of recombination of carriers in the silicon substrate is reduced. Thus, it is difficult to maintain the function of controlling the life time of carriers. Up to now, the technology that makes it possible to reduce the leakage current and at the same time exhibit the life-time control function has not been established yet.

### SUMMARY OF THE INVENTION

The invention provides a semiconductor device, with which it is possible to reduce the leakage current and at the same time maintain the function of controlling the life time of carriers.

A method of producing a semiconductor device according to a first aspect of the invention is a method of producing a semiconductor device, in which a plurality of crystal defects for controlling life time of carries are formed in a silicon substrate. The method includes: a crystal defect forming step of forming the plurality of crystal defects in the silicon substrate; and a termination step of performing termination of the plurality of crystal defects fanned in the silicon substrate to make the total number of the crystal defects that cause a trap level that, differs from the energy level of the center of a band gap by less than 0.2 eV, less than the number of the crystal defects that cause the trap level that is the closest to the energy level of the center of the band gap among the trap levels that differ from the energy level of the center of the band gap by 0.2 eV or more.

According to the method of the first aspect, the crystal defects that cause the deep trap level that has a strong influence on the leakage current are reduced by terminating such crystal defects to a greater extent than the extent to which the crystal defects that cause the shallow trap levels are terminated. Thus, it is possible to reduce the leakage current. Meanwhile, the crystal defects that cause the shallow trap levels that have a weak influence on the leakage current are terminated to a lesser extent than the extent to which the crystal defects that cause the deep trap level are terminated. Thus, a large number of the crystal defects that cause the shallow trap levels remain in the silicon substrate. Thus, the function of controlling the life time of carriers is maintained.

In the method of the above first aspect, the total number of the crystal defects that cause a trap level that differs from the energy level of the center of the band gap by less than 0.2 eV may be made greater than the, number of the crystal defects that cause the trap level that is the second closest to the energy level of the center of the band gap among the trap levels that differ from the energy level of the center of the band gap by 0.2 eV or more.

When a large number of the crystal defects formed in the silicon substrate, are terminated, it is possible that the life-time control function is not maintained. When the total number of the crystal defects that cause a trap level that differs from the energy level of the center of the band gap by less than 0.2 eV is made greater than the number of the crystal defects that cause the trap level that is the second closest to the energy level of the center of the band gap among the trap levels that differ from the energy level of the center of the band gap by 0.2 eV or more, it is possible to secure a sufficient number of crystal defects to maintain the life-time control function. Thus, it is possible to reduce the leakage current and at the same time it is ensured that the life-time control function is maintained.

A semiconductor device according to a second aspect of the invention includes a silicon-substrate having a plurality of crystal defects for controlling life time of carries. In this semiconductor device, the total number of the crystal defects that cause a trap level that differs from the energy level of the center of the band gap by, less than 0.2 eV, is less than the number of the crystal defects that cause the trap level that is the closest to the energy level of the center of the band gap among trap levels that differ from the energy level of the center of the band gap by 0.2 eV or more.

According to the semiconductor device of the second aspect, the total number of the crystal defects that cause the deep trap level has strong influence on the amount of leakage current is less than the number of the crystal defects that cause the trap level that is the closest to the energy level of the center of the band gap among the shallow trap levels that have a weak influence on the leakage current. Thus, the leakage current is reduced. On the other hand, a plurality of the crystal defects that cause the shallow trap levels remain in the silicon substrate and the function of controlling the life time of carriers is therefore maintained.

In the semiconductor device of the second aspect, the total number of the crystal defects that cause the trap level that differs from the energy level of the center of the band gap by less than 0.2 eV may be made greater than the number of the crystal defects that cause the trap level that is the second closest to the energy level of the center of the band gap among the trap levels that differ from the energy level of the center of the band gap by 0.2 eV or more.

When a large number of the crystal defects formed in the silicon substrate are terminated, it is possible that the life-time control'function is not maintained. When the total number of the crystal defects that cause a trap level that differs from the energy level of the center of the band gap by less than 0.2 eV is made greater than the number of the crystal defects that cause the trap level that is the second closest to the energy level of the center of the band gap among the trap levels that differ from the energy level of the center of the band gap by 0.2 eV or more, it is possible to secure a sufficient number of crystal defects to maintain the life-time control function. Thus, it is possible to reduce the leakage current and at the same time it is ensured that the life-time control function is maintained.

According to the invention, a semiconductor device is provided, with which it is possible to reduce the leakage current while maintaining the function of controlling the life time of carriers.

### BRIEF DESCRIPTION OF THE DRAWINGS

The foregoing and further objects, features and advantages of the invention will become apparent from the following description of example embodiments with reference to the accompanying drawings, wherein like numerals are used to represent, like elements and wherein:

FIG. 1 is a sectional diagram of a semiconductor device 100 according to a first example of the invention;

FIG. 2 shows a first step of a method of producing the semiconductor device 100;

FIG. 3 shows a second step of the method, of producing the semiconductor device 100;

FIG. 4 shows a third step of the method of producing the semiconductor device 100;

FIG. 5 shows a fourth step of the method of producing the semiconductor device 100;

FIG. 6A is a schematic diagram showing a bonding state of silicon atoms in the vicinity of a crystal defect 14a before a termination step;

FIG. 6B is a schematic diagram showing a bonding state of the silicon atoms in the vicinity of the crystal defect 14a after the termination step;

FIG. 7A is a schematic diagram showing energy levels within the band gap in a silicon substrate before the termination step;

FIG. 7B is a schematic diagram showing the energy levels within the band gap in the silicon substrate after the termination step;

FIG. 8 shows a first step of a method of producing a semiconductor device 200 according to a second example of the invention;

FIG. 9 shows a second step of the method of producing the semiconductor device 200;

FIG. 10 shows a third step of the method of producing the semiconductor device 200;

FIG. 11 shows a fourth step of the method of producing the semiconductor device 200;

FIG. 12A is a schematic diagram showing a bonding state of silicon atoms in the vicinity of a crystal defect 44a before a termination step;

FIG. 12B is a schematic diagram showing a bonding state of the silicon atoms in the vicinity of the crystal defect 44a after the termination step;

FIG. 13 shows a first step of a method of producing a semiconductor device 300 according to a third example of the invention;

FIG. 14 shows a second step of the method of producing the semiconductor device 300;

FIG. 15 shows a third step of the method of producing the semiconductor device 300;

FIG. 16A is a schematic diagram showing a bonding state of silicon atoms in the vicinity of a crystal defect 74a before a termination step;

FIG. 16B is a schematic diagram showing a bonding state of the silicon atoms in the vicinity of the crystal defect 74a after the termination step;

FIG. 17 is a graph showing a relation between the leakage current and the energy level difference between each trap level and the center of the band gap;

FIG. 18 is a graph showing the relation between the trap density of each trap level and the leakage current;

FIG. 19 is a graph showing a relation between the trap density of each trap level and the forward direction voltage;

FIG. 20 is a graph showing the relation between the forward direction voltage and the leakage current in the cases of a semiconductor device according to the invention and a conventional semiconductor device;

FIG. 21 shows the result of the measurement conducted by the DLTS method, showing the relation between the trap level and the trap density of each trap level in a conventional semiconductor device; and

FIG. 22 shows the result of the measurement conducted by the DLTS method, showing the relation between the trap level and the trap density of each trap level in a semiconductor device according to the invention.

### DETAILED DESCRIPTION OF EMBODIMENTS

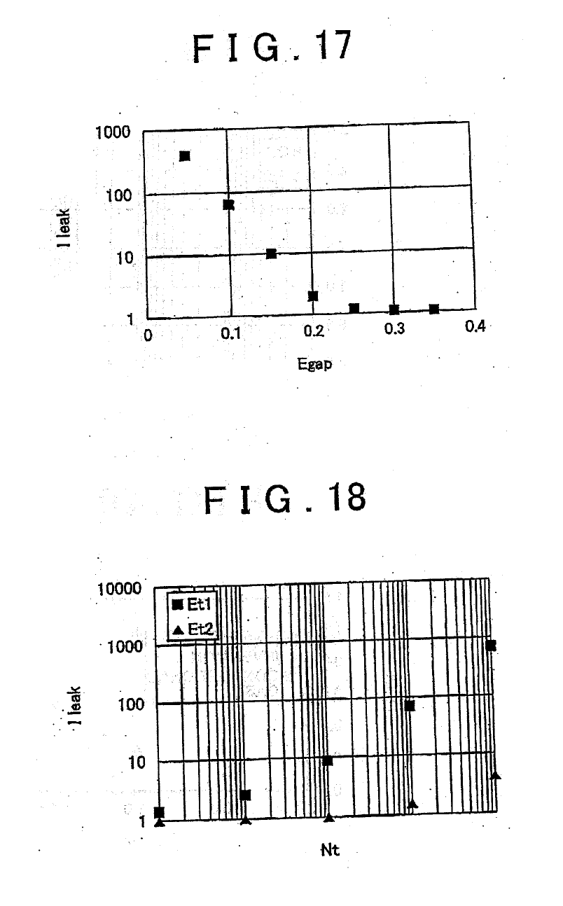

In order to solve the above described problem, researchers, involved in the invention studied the relation between the crystal defects and the leakage current in diodes. As a result, the following has been found. FIG. 17 is a gyaph showing the relation between the leakage current and the energy. level difference between each trap level and the center of the band gap. In FIG. 17, the horizontal axis indicates the energy level difference Egap (eV) from the center of the band gap and the vertical axis indicates the normalized electric current value Ileak (A) of the leakage current that is caused by the crystal defects formed in the silicon substrate. The energy level difference Egap from the center of the band gap increases as the depth of the trap level decreases. As shown in FIG. 17, as the energy level difference Egap from the center of the band gap decreases (as the depth of the trap level increases), the electric current value Ileak of the leakage current increases. In particular, the leakage current lleak shows rapid increase from the point at which the energy level difference Egap from the center of the band gap is 0.2 eV In the following description, the trap level, at which the energy level deviation from the center of the band gap is less than 0.2 eV, is referred to as the deep trap level. The trap level, at which the energy level deviation from the center of the band gap is equal to or greater than 0.2 eV, is referred to as the shallow trap level. From the graph shown in FIG. 17, it can be seen that the electric current value Ileak of the leakage current is heavily dependent on the crystal defects that cause the deep trap level.

FIG. 18 is a graph showing the relation between the trap density of each trap level and the leakage current. In FIG. 18, the horizontal axis indicates the trap density Nt (cm⁻³) of each trap level that is formed within the band gap in the silicon substrate. The trap density Nt increases from the left side to the right side in FICA 18. The vertical axis indicates the normalized electric current value Ileak (A) of the leakage current. In the following description, Et1 expresses the deep trap level and Et2 expresses the shallow trap level. As shown in FIG. 18, with regard to the crystal defects that cause the deep trap level Et1, as the trap density Nt of the trap level increases, the electric current value Ileak of the leakage current increases. On the other hand, with regard to the, crystal defects that cause the shallow trap level Et2, the increase in the ,electric current value Ileak of the leakage current is low even when the trap density of the trap level increases. Thus, it can be seen that the electric current value Ileak of the leakage current is more heavily dependent on the density of the crystal defects that cause the deep trap level Et1 than on the density of the crystal defects that cause the shallow trap level Et2.

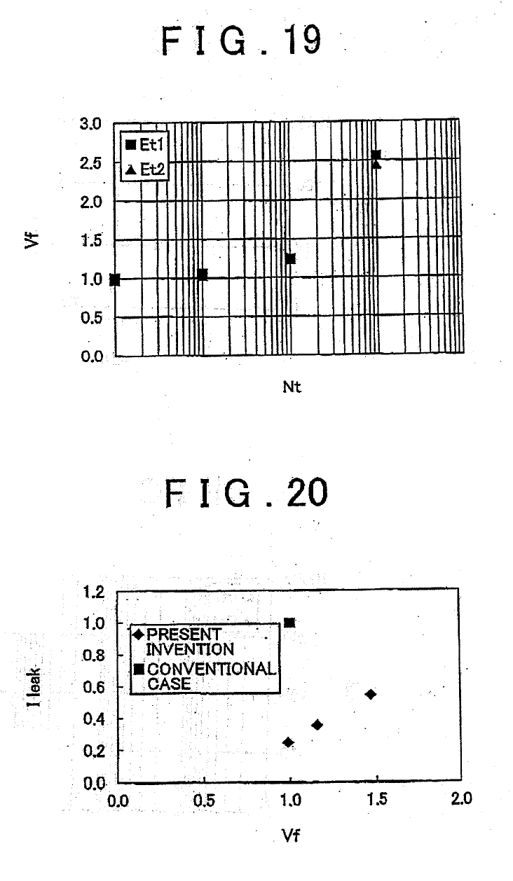

FIG. 19 is a graph showing a relation between the trap density of each trap level and the forward direction voltage. Because the forward direction voltage increases when the life time of carriers is reduced, it is possible to evaluate the life-time control function by measuring the forward direction voltage. In FIG, 19, the horizontal axis indicates the trap density Nt (cm⁻³)of each trap level and the trap density Nt increases from the left side to the right side in FIG. 19. The vertical axis indicates the normalized forward direction voltage Vf (V). In a semiconductor device, the forward direction voltage Vf increases as the life time of carriers is reduced. In other words, as the trap density Nt of the trap level increases; the forward direction voltage Vf increases. In the graph shown in FIG. 19, the forward direction voltage Vf increases as the trap density. Nt of the trap level increases in either of the cases of the deep trap level Et1 and the shallow trap level Et2. Thus, it can be seen that the dependency of the forward direction voltage Vf on the depth of the trap level is low. In other words, it can be seen that the dependency of the life-time control function on the depth of the trap level is low.

From the graphs shown in FIGS. 17 to 19, it can be seen that by reducing the crystal defects that cause the deep trap level Et1 to a greater extent than the extent to which the crystal defects that cause the shallow trap level Et2 is reduced, it is possible to reduce the electric current value Ileak of the leakage current without changing the forward direction voltage Vf. In other words, it can be seen that it is possible to reduce the electric current value Ileak of the leakage current without impairing the function of controlling the life time of carriers. It should be noted that such a tendency is not seen only in the diode but seen in all the semiconductor devices that have the life-time control function.

The invention has been made based on the above findings. Specifically, the invention provides a semiconductor device, with which it is possible to reduce the leakage current while maintaining the function of controlling the life time of carriers, and the invention also provides a method of producing such a semiconductor device.

FIG. 20 is a graph showing the relation between the forward direction voltage and the leakage current of the semiconductor devices that are produced by a conventional producing method and by a method according to the invention, respectively. In FIG. 20, the horizontal axis indicates the normalized forward direction voltage Vf (V). The vertical axis indicates the normalized electric current value Ileak (A) of the leakage current. As shown in FIG. 20, when semiconductor devices that have the life-time control function and that show similar forward direction voltages are produced, it can be seen from the data, for which the forward direction voltage is 1.0, for example, that in the semiconductor device produced by the method according to the invention, the leakage current is reduced by approximately 75% as compared to the leakage current in the conventional semiconductor device. With the method according to the invention, it is possible to produce a semiconductor device, with which it is possible to reduce the leakage current while maintaining the function of controlling the life time of carriers at a level equivalent to that of the life-time control function of the conventional semiconductor device.

Preferable features of the examples described below are as follows: (First Feature) When accelerated irradiation of helium ions is performed, the acceleration energy is adjusted depending on the positions at which the crystal defects are formed; (Second Feature) When accelerated irradiation of helium ions is performed, the thickness of the absorber is adjusted depending on the positions at which the crystal defects are formed; (Third Feature) The total number of the crystal defects that cause a trap level that differs from the energy level of the center of the band gap by less than 0.2 eV is set greater than the number of the crystal defects that cause the trap level that is the second closest to the center of the band gap among the trap levels that differ from the energy level of the center of the band gap by 0.2 eV or more.

### First Example

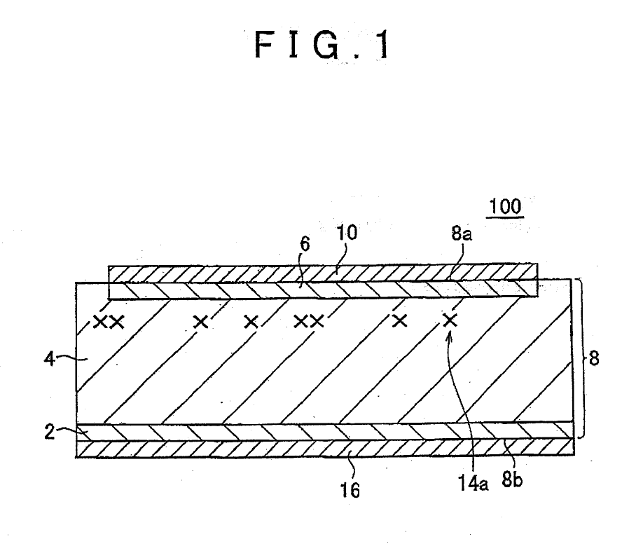

FIG. 1 is a sectional diagram of a semiconductor, device 100 according to a first example of the invention. The semiconductor device 100 is a diode. The semiconductor device 100 includes an anode electrode 10 that is placed on a first surface 8a of a silicon substrate 8 and a cathode electrode 16 that is placed on a second surface 8b of the silicon substrate & In the silicon substrate 8, an anode region 6, a cathode region 2, a drift region 4, and a plurality of crystal defects 14a are. disposed. The anode region 6 is a p⁺-type region and is disposed in part of the silicon substrate 8 on the first surface 8a side thereof The cathode region 2 is an n⁺-type region and is disposed in the silicon substrate 8 on the second surface 8b side thereof The drift region 4 is an n⁻-type region and is disposed between the anode region 6 and the cathode region 2 in the silicon substrate 8. In the silicon substrate 8, there is a band gap (not shown) and the crystal defects 14a provide the trap levels within the band gap. In the semiconductor device 100, the total number of the crystal defects 14a that cause a trap level that differs from the energy level of the center of the band gap by less than 0.2 eV is less than the number of the crystal defects 14a that cause the trap level that is the closest to the energy level of the center of the band gap among the trap levels that differ from the energy level of the center of the band gap by 0.2 eV or more

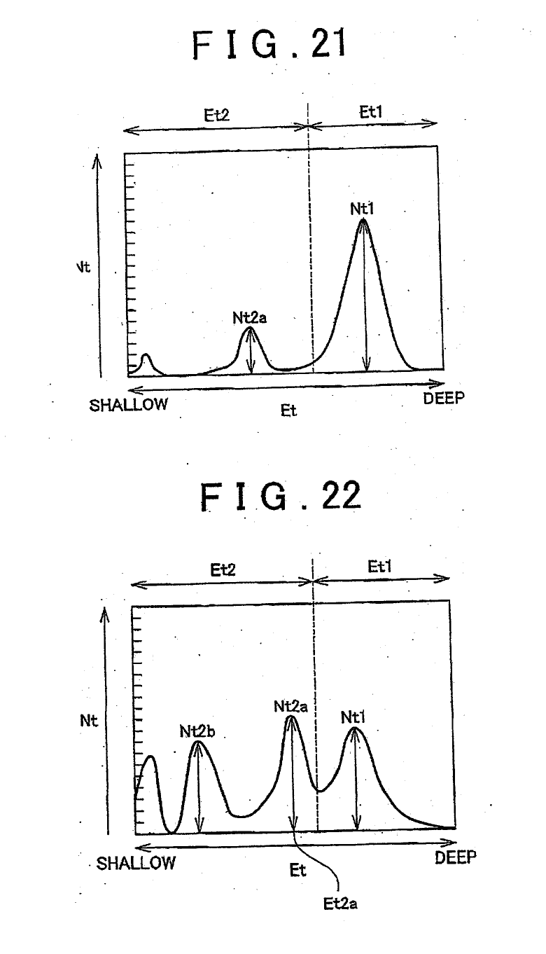

The number of the crystal defects 14a that are disposed in the silicon substrate 8 can be measured by the Deep Level Transient Spectroscopy (DLTS) method, for example. FIGS. 21 and 22 show the result of measurement by the DLTS method. FIG. 21 shows the relation between the trap level Et and the trap density Nt of each trap level in a conventional semiconductor device having the life-time control function. FIG. 22 shows the relation between the trap level Et and the trap density Nt of each trap level in the semiconductor device 100 of this example. In FIGS. 21 and 22, the horizontal axis indicates the trap level Et formed within the band gap of the silicon substrate and the energy level of the trap level becomes closer to the energy level of the center of the band gap in the direction from the left side to the right side in these figures. The vertical axis indicates the trap density Nt of each trap level and the trap density Nt increases from the bottom side to the top side in these figures. Nt1 in FIGS. 21 and 22 expresses the trap density of the deep trap level En. Nt2a in FIGS. 21 and 22 expresses the trap density of the trap level that is the closest to the energy level of the center of the band, gap among the shallow trap levels Et2. Nt2b in FIG. 22 expresses the trap density of the trap level that is the second closest to the energy level of the center of the band gap among the shallow trap levels Et2. The trap density is proportional to the number of crystal defects.

As shown in FIGS. 21 and 22, the result of measurement by the DLTS method gives continuous values. However, the trap levels exist at the positions of the peaks shown in these figures and there is no trap level at the other energy levels. As shown in FIG. 21, it can be seen that the trap density Nt1 of the deep trap level Et1 is approximately three to four times as high as the trap density Nt2a of the shallow trap level Et2. On the other hand, as shown in FIG. 22, it can be seen that in the semiconductor device 100 of this example, the trap density Nt1 of the deep trap level Et1 is less than the trap density Nt2a of the shallow trap level Et2.

Assuming that the width of the crystal defect 14a is d, the trap density of the deep trap level Et1 is Nt1n, the capture cross section of the deep trap level Et1 is σ1n, the trap density of the shallow trap level Et2 is Nt2, and the capture cross section of the shallow trap level Et2 is σ2, the following expression (1) is satisfied in the case of a conventional semiconductor device, having the life-time control function, shown in FIG. 21. On the other hand, in the case of the semiconductor device 100 of this example shown in FIG. 22, the following expressions (2) and (3) are satisfied.

Σ(Nt1n×σ1n×d)>Nt2a×σ2×d (1)

Σ(Nt1n×σ1n×d)<Nt2a×σ2×d (2)

Nt2a>Nt1>Nt2b (3)

The trap density is proportional to the number of crystal defects. Thus, the expression (1) implies that the total number of the crystal defects that cause a trap level that differs from the energy level of the center of the band gap by less than 0.2 eV, is greater than the number of the crystal defects that cause the trap level (Et2a) that is the closest to the energy level of the center of the band gap among the trap levels that differ from the energy level of the center of the band gap by 0.2 eV or more. The expression (2) implies that the total number of the crystal defects that cause a trap level that differs from the energy level Ei of the center of the band gap by less than 0.2; eV is less than the number of the crystal defects that cause the trap level (Et2a) that is the closest to the center of the band gap among the trap levels that differ from the energy level Ei of the center of the band gap by 0.2 eV or more. The expression (3) implies that the total number of the crystal defects that cause a trap level that differs from the energy level of the center of the band gap by less than 0.2 eV, is less than the number of the crystal defects that cause the trap level (Et2a) that is the closest to the energy level of the center of the band gap among the trap levels that differ from the energy level of the center of the band gap by 0.2 eV or more The expression (3) also implies that the same total number is greater than the number of the crystal defects that cause the trap level (Et2b) that is the second closest to the energy level of the center of the band gap among the trap levels that differ from the energy level of the center of the band gap by 0.2 eV or more.

With the semiconductor device 100 of this example, the total number of the crystal defects that cause the deep trap level Et1 that has a strong influence on the amount of leakage current is less than the number of the crystal defects that cause the trap level (Et2a) that is the closest to the energy level of the center of the band gap among the shallow trap levels Et2 that have a weak influence on the leakage current. Thus, the leakage current is reduced. On the other hand, a plurality of the crystal defects that cause the shallow trap levels Et2 remain in the silicon substrate and, the function of controlling the life time of carriers is maintained. In addition, although in the semiconductor device in which the crystal defects are provided in the silicon substrate, in general, there is a tendency that the leakage current increases as the temperature increases, the leakage current is reduced even under high temperature conditions in the case of the semiconductor device 100 because the number of the crystal defects that cause the deep

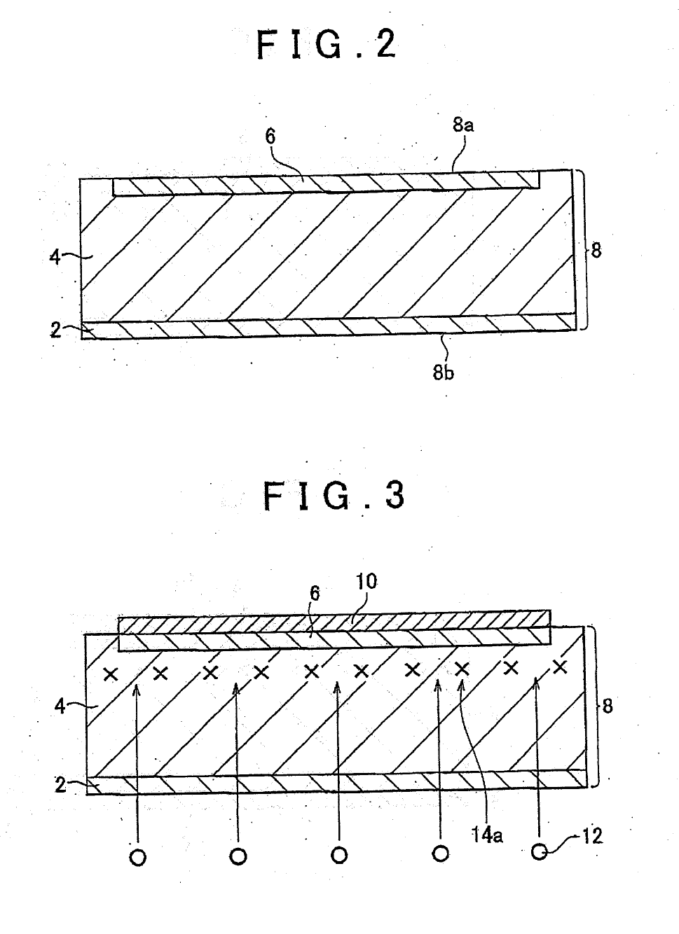

Next, referring to FIGS. 2 to 5, a method of producing the semiconductor device 100 of the first example will be described. As shown in FIG. 2, an n⁻-type silicon substrate 8 is prepared. Next, n-type impurity, such as phosphorus, is implanted into the silicon substrate 8 through the second surface 8b thereof and is thermally diffused, whereby the n⁺-type Cathode region 2 is formed in the silicon substrate 8 on the second surface 8b side thereof. Then, p-type impurity, such as boron, is implanted into the silicon substrate 8 through the first surface 8a thereof and is thermally diffused, whereby the p⁺-type anode region 6 is formed in part of the silicon substrate 8 on the first surface 8a side thereof. The region in the silicon substrate 8, in which neither the cathode region 2 nor the anode region 6 is formed, is the n⁻-type drift region 4.

Next, as shown in FIG. 3, the anode electrode 10 that abuts the anode region 6 is formed on the first surface 8a of, the silicon substrate 8. Next, the second surface 8b of the silicon substrate 8 is irradiated with the accelerated helium ions 12. In this way, a plurality of crystal defects 14a are formed in the silicon substrate 8 (crystal-defect forming step).

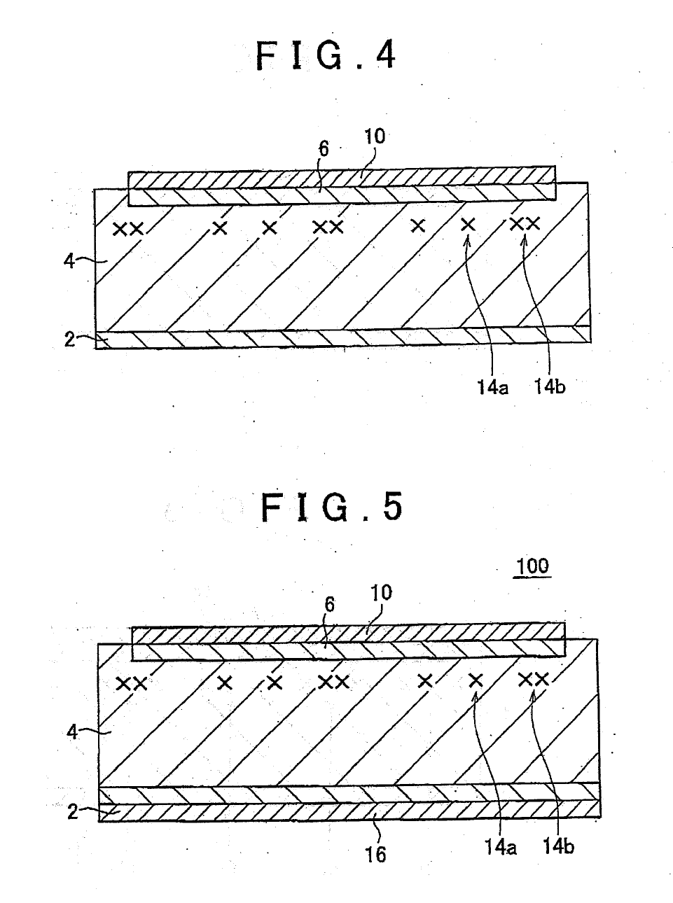

Next, as shown in FIG. 4, hydrogen (not shown) is introduced into the silicon substrate 8 (termination step). As a method of introducing hydrogen, a method in which a silicon substrate 8 is heated in a diffusion furnace and hydrogen gas is flown thereon, a method in which hydrogen ions are implanted into a silicon substrate 8, which is then heated, etc. can be used The hydrogen atoms introduced into the silicon substrate 8 are diffused by heating. When the diffused hydrogen ions move to the crystal defects 14a, the crystal defects 14a are terminated. The reference numeral 14b designates the crystal defects that recover due to the termination process. When hydrogen is introduced into the silicon substrate by implanting hydrogen ions into the substrate and heating it, it is possible to adjust the positions, at which the hydrogen ions are implanted, and the diffusion range, by adjusting the hydrogen implantation conditions. The details of the hydrogen implantation conditions will be described later. Although hydrogen is introduced into the silicon substrate 8 in this example, deuterium or tritium may be introduced into the silicon substrate 8.

Next, as shown in FIG. 5, the cathode electrode 16 that abuts the cathode region 2 is formed on the second surface 8b of the silicon substrate & The semiconductor device 100 is completed through the above steps.

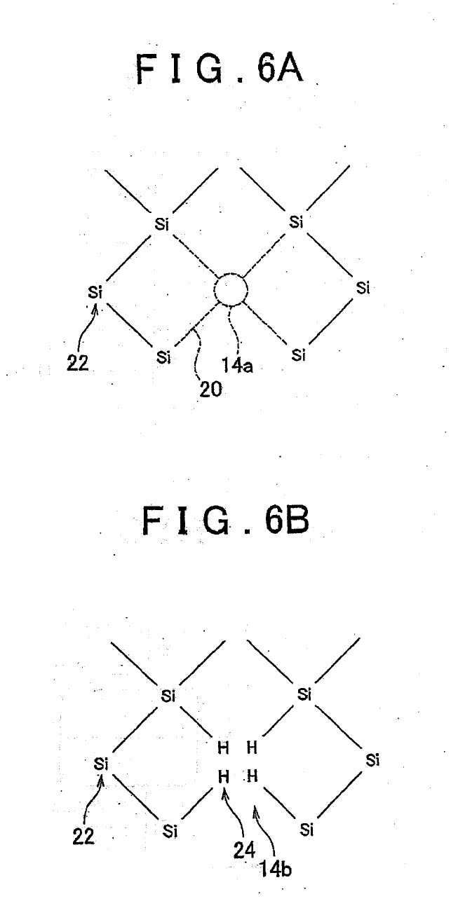

FIG. 6A is a schematic diagram showing a bonding, state of the silicon atoms in the vicinity of the crystal defect 14a before the termination step. In FIG. 6A, the reference numeral 22 designates a silicon atom. The broken line 20 represents a dangling bond of a silicon atom. FIG. 6B is a schematic diagram showing a bonding state of the silicon atoms in the vicinity of the crystal defect 14a after the termination step. As shown in FIG. 6B, when hydrogen atoms 24 move to the crystal defect 14a, the hydrogen atoms 24 are bonded with the dangling bonds 20, whereby the crystal defect 14a is terminated. Thus, the crystal defect 14a recovers, which is shown at 14b.

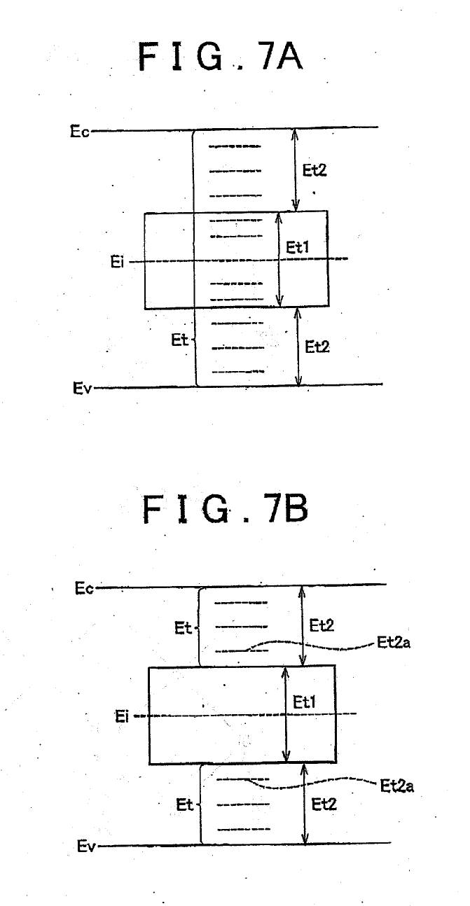

FIG. 7A is a schematic diagram, showing energy levels within the band gap in the silicon substrate 8 before the termination step. In FIG. 7A, Ec expresses the conduction band and By expresses the valence band. Ei expresses the center of the band gap. Et expresses the trap levels. Among the trap levels Et, Et1 expresses the deep trap level. Et2 expresses the shallow trap levels. FIG. 7B is a schematic diagram showing the energy levels within the band gap in the silicon substrate 8 after the termination step. In FIG. 7B, Et2a expresses the trap level that is the closest to the energy level Ei of the center of the band gap among the shallow trap levels Et2. As shown in FIG. 7B, when the crystal defect 14a of the deep trap level Et1 is terminated, the crystal defect 14a of the deep trap level Et1 recovers. The crystal defect 14a of the deep trap level Et1 that has recovered vanishes. Note that, in FIG. 7B, although the broken lines representing the deep trap level Et1 are erased to facilitate understanding of the state where the crystal defects 14a that cause the trap level Et1 are eliminated, not all of the crystal defects 14a that cause the trap level Et1 are eliminated by the termination process, that is, part of such crystal defects 14a are eliminated by the termination process.

In the producing method of this example, a method, in which hydrogen ions are implanted into the silicon substrate 8 and the substrate 8 is then heated, can be used as a method of introducing hydrogen in the termination step. In this case, an, example of conditions for the hydrogen ion implantation is, for example, as follows: the acceleration energy is 4 MeV or 8 MeV; the amount of irradiation is 6×10¹² (cm⁻²). An example of the conditions for heat treatment is as follows: the atmosphere is a nitrogen atmosphere or a hydrogen atmosphere; the heating temperature is 400° C.; the heat treatment time is 30 minutes. By introducing hydrogen into the silicon substrate 8 under such conditions, it is possible to produce the semiconductor device 100 that satisfies the above expression (2).

With the producing method of this example, the crystal defects that cause the deep trap level Et1 are terminated to a relatively greater extent, so that the, total number of the crystal defects that cause the deep trap level is reduced. Thus, it is possible to reduce the leakage current. Meanwhile, the number of the crystal defects that cause the shallow trap level Et2 and that are terminated is less than the number of the crystal defects that cause the deep trap level Et1 and that are terminated. Thus, a plurality of the crystal defects that cause the shallow, trap level Et2 remain in the silicon substrate 8. Thus, the function of controlling the life time of carriers is maintained. With the semiconductor device 100 that is produced by this method, it is possible to reduce the leakage current while maintaining the function of controlling the life time of carriers.

### Second Example

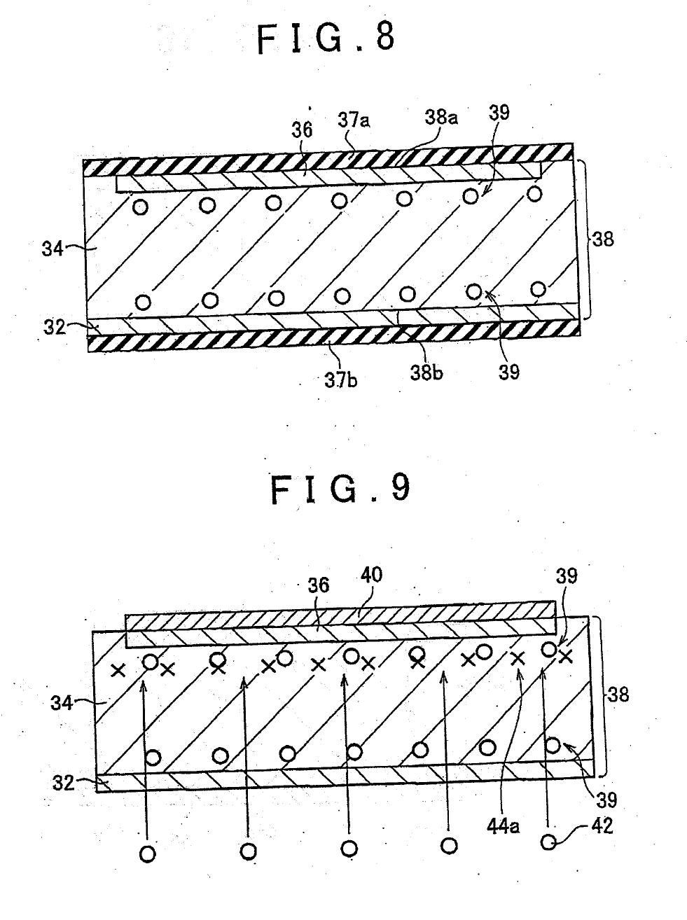

FIGS. 8 to 11 illustrate a method of producing a semiconductor device 200 of a second example of the invention. The semiconductor device 200 is a diode. The semiconductor device 200 has the same structure as that of the semiconductor device 100 and differs from the semiconductor device 100 only in the method of forming the crystal defects and the method of, terminating the crystal defects. Thus, in FIG. 8, the portions designated by the reference numerals obtained by adding 30 to the reference numerals in FIG. 2 are the same portions as the corresponding portions described referring to FIG. 2 and the repetitive description thereof is omitted. The process for forming a cathode region 32 in a silicon substrate 38 on the second surface 38b side, thereof is similar to that of the producing method of the first example and the description thereof is omitted. In this example, after forming the cathode region 32, as shown in FIG. 8, p-type impurity, such as boron, is implanted into the silicon substrate 38 through a first surface 38a thereof and is thermally diffused, whereby a p⁺-type anode region. 36 is formed in the silicon substrate 38 on the first surface 38a side thereof. When this is performed, thermal oxidation films 37a and 37b are formed on the first surface 38a and the second surface 38b of the silicon substrate 38 by performing thermal diffusion in an oxygen atmosphere. When the thermal oxidation films 37a and 37b are formed, a plurality of, interstitial silicon atoms 39 occur in the silicon substrate 38 on the first surface 38a side and the second surface 38b side thereof.

Next, as shown in FIG. 9, the thermal oxidation films 37a and 37b are removed. Then, an anode electrode 40 that abuts the anode region 36 is formed on the first surface 38a of the silicon substrate 38. Thereafter, the second surface 38b of the silicon substrate 38 is irradiated with the accelerated helium ions 42. Thus, a plurality of crystal defects 44a are formed in the silicon substrate 38 (crystal-defect forming step).

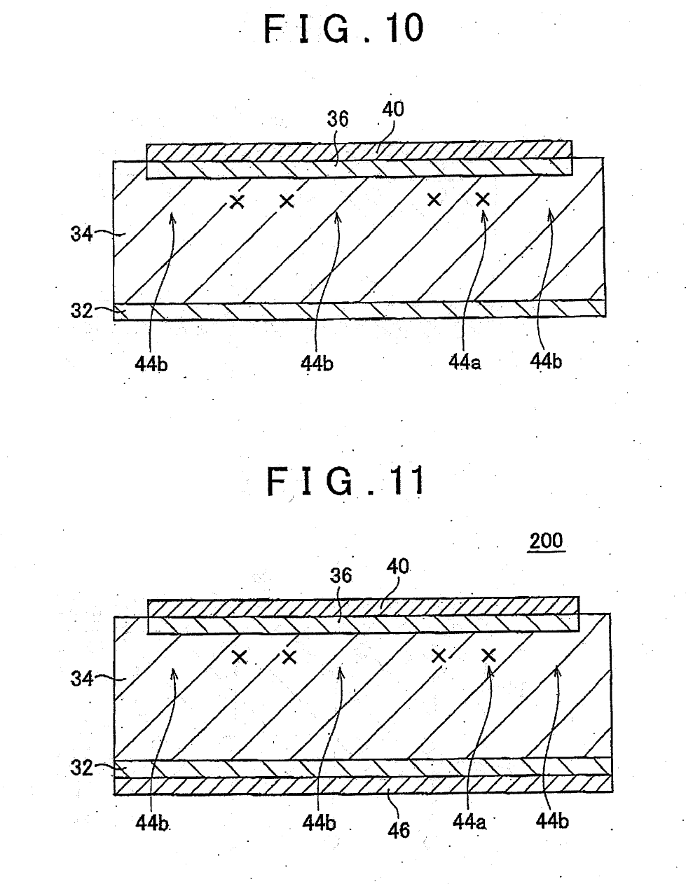

Next, as shown in FIG. 10, the silicon substrate 38 is thermally treated (termination step), so that the interstitial silicon atoms 39 in the silicon substrate 38 are heated and diffused. When the diffused silicon atoms 39 move to the crystal defects 44a, the crystal defects 44a are terminated. Reference numerals 44b designate the crystal defects that have recovered and vanished due to the termination process. When this is performed, it is possible to adjust the diffusion range of the silicon atoms 39 by adjusting the thermal treatment conditions.

Next, as shown in FIG. 11, a cathode electrode 46 that abuts the cathode region 32 is formed on the second surface 38b of, the silicon substrate 38. The semiconductor device 200 is completed through the above steps.

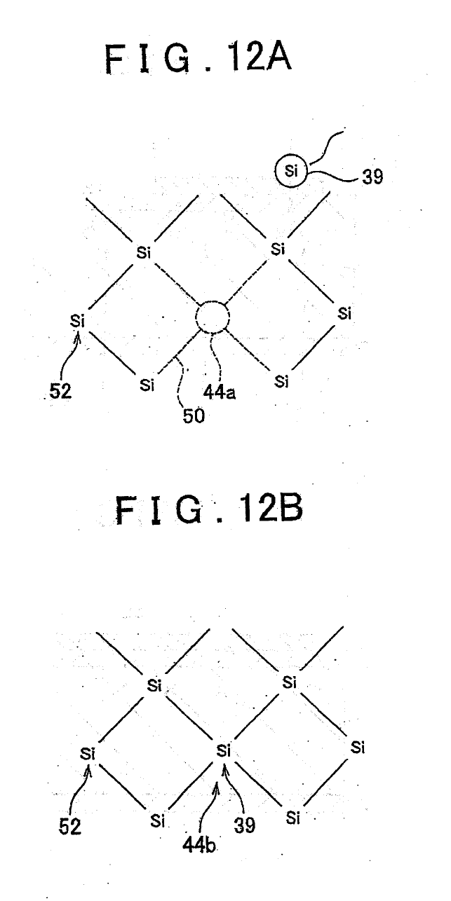

FIG. 12A is a schematic diagram showing the bonding state of the silicon atoms in the vicinity of the crystal defect 44a before the termination step. In FIG. 12A, the reference numeral 52 designates a silicon atom. The broken line 50 represents a dangling bond of a silicon atom. FIG. 12B is a schematic diagram showing the bonding state of the silicon atoms in the vicinity of the crystal defect 44a after the termination step. As shown in FIG. 12B, when an interstitial silicon atom 39 moves to the crystal defect 44a, the interstitial silicon atom 39 is bonded with the dangling bonds 50, whereby the crystal defect 44a is terminated. Thus, the crystal defect 44a recovers, which is shown at 44b.

In the producing method of this example, the total number of, the crystal defects that cause the deep trap level Et1 shown in FIGS. 7A and 7B is made less than the number of the crystal defects that cause the trap level Et2a by adjusting the diffusion range of the interstitial silicon atoms 39. Thus, it is possible to produce the semiconductor device, with which it is possible to reduce the leakage current while maintaining the function of controlling the life time of carriers. In addition, according to the producing method of this example, it is possible to, terminate the crystal defects 44a in the silicon substrate 38 without introducing impurity, such as hydrogen, into the silicon substrate 38.

### Third Example

FIGS. 13 to 15 show a method of producing a semiconductor device 300 according to a third example of the invention. The semiconductor device 300 is a diode. The semiconductor device 300 has the same structure as that of the semiconductor device 100 and differs from the semiconductor device 100 only in the method of forming the crystal defects and the method of terminating the crystal defects. Thus, in FIG. 13, the portions designated by the reference numerals obtained by adding 60 to the reference numerals in FIG. 2 are the same portions as the corresponding portions described referring to FIG. 2 and the repetitive description thereof is omitted. The process for forming an anode region 66 and a cathode region 62 in a silicon substrate 68 on the first surface 68a side and the second surface 68b side thereof, respectively, is similar to that of the producing method of the first example and the description thereof is emitted. In this example, after forming the anode region 66, as shown in FIG. 13, an anode, electrode 70 that abuts the anode region 66 is formed on the silicon substrate 68 on the first surface 68a side thereof. Then, the second surface 68b of the silicon substrate 68 is irradiated with accelerated helium ions 72. In this way, a plurality of crystal defects 74a are formed in the silicon substrate 68 (crystal-defect forming step). Next, oxygen ions 67 are implanted toward the location, in which the crystal defects 74a are formed, through the first surface 68a of the silicon substrate 68. When this is performed, it is possible to adjust the location, into which the oxygen ions 67 are implanted, by adjusting the implantation conditions. In this example, the oxygen ions 67 are implanted into the silicon substrate 68. However, carbon ions or fluorine ions, may be implanted into the silicon substrate 68. The oxygen ions 67 may be implanted through the second surface 68b of the silicon substrate 68.

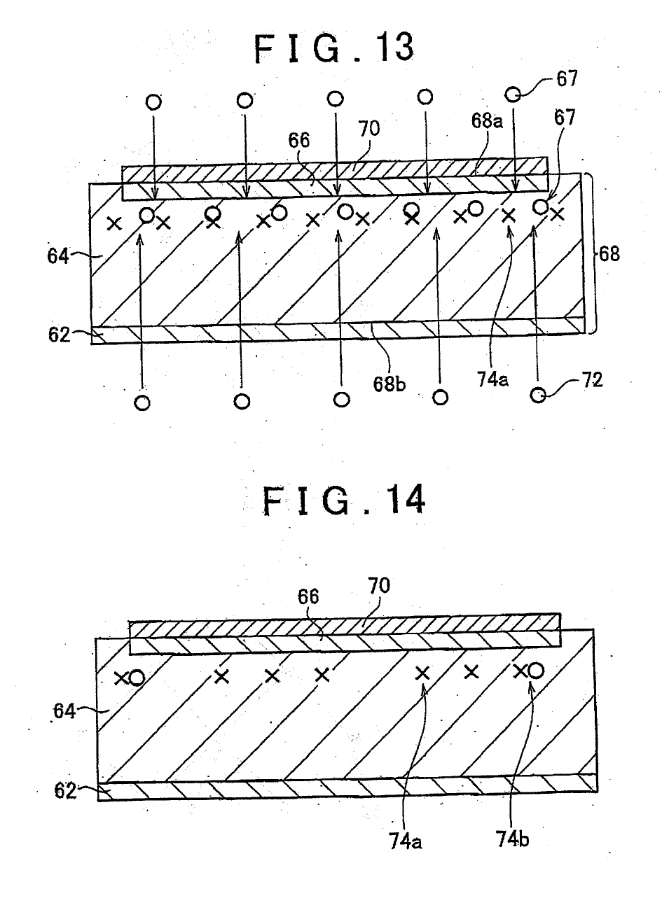

Next, as shown in FIG. 14, the silicon substrate 68 is thermally treated (termination step). In this way, the oxygen ions 67 in the silicon substrate 68 are diffused. When the diffused oxygen ions 67 move to the crystal defect 74a, the, crystal defect 74a is terminated. Reference numeral 74b expresses the crystal defect that has recovered due to the termination process. When this is performed, it is possible to adjust the diffusion range of the oxygen ions 67 by adjusting the thermal treatment conditions.

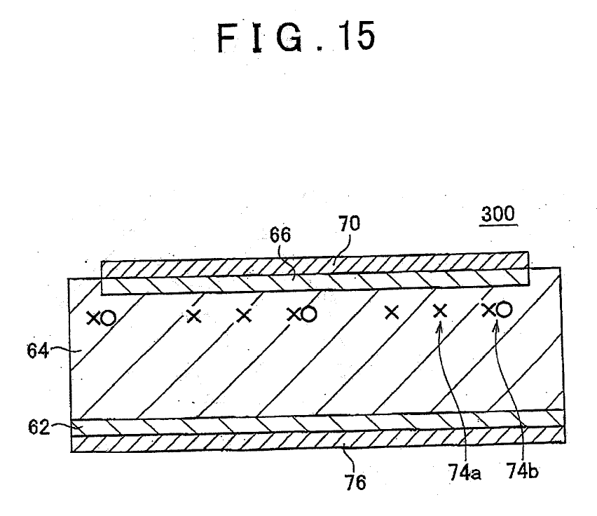

Next, as shown in FIG. 15, the cathode electrode 76 that abuts the cathode region 62 is formed on the silicon substrate 68 on the second surface 68b side thereof. The semiconductor device 300 is completed through the above steps.

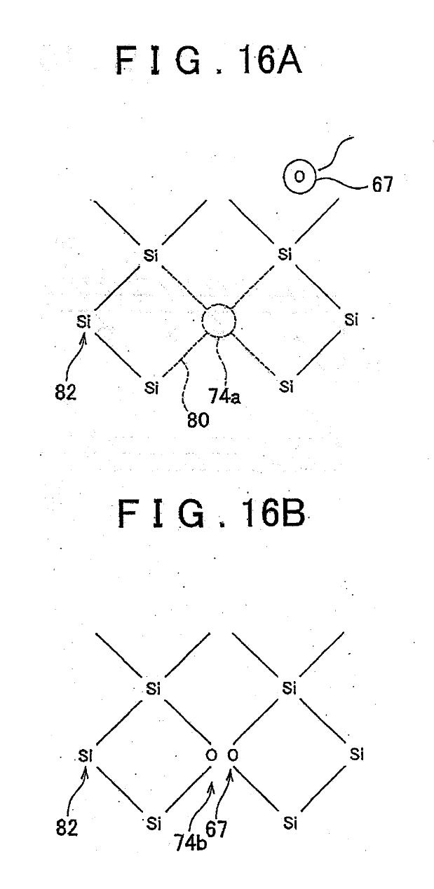

FIG. 16A is a schematic diagram showing the bonding state of the silicon atoms in the vicinity of the crystal defect 74a before the termination step. In FIG. 16A, the reference numeral 82 designates a silicon atom. The broken line 80 represents a dangling bond of a silicon atom. FIG. 16B is a schematic diagram showing the bonding state of the silicon atoms in the vicinity of the crystal defect 74a after the termination step. As shown in FIG. 16B, when the oxygen atoms 67 move to the crystal defect 74a, the oxygen ions 67 are bonded with the dangling bonds 80, whereby the crystal defect 74a is terminated. Thus, the crystal defect 74a recovers, which is shown at 74b.

In the producing method of this example, the total number of the crystal defects that cause the deep trap levels ‘Et1’ shown in FIGS. 7A and 7B is made less than the number of the crystal defects that cause the trap level: Et2a by adjusting the implantation range and the diffusion range of the oxygen ions 67. Thus, it is possible to produce the semiconductor device, with which it is possible to reduce the leakage current while maintaining the function of controlling the life time of carriers. In addition, with the producing method .of this example, it is possible to terminate the crystal defects 74a in the silicon substrate 68 even when ions other than hydrogen ions are implanted into the silicon substrate 68.

In the producing methods of the first to third examples, it is preferable that the acceleration energy for irradiation be adjusted depending on the locations in which the crystal defects are formed during the accelerated irradiation of the helium ions. It is also preferable that the thickness of the absorber be adjusted depending on the locations, in which the crystal defects are formed. By adjusting the acceleration energy and the thickness of the absorber during the accelerated irradiation of the helium ions, it is possible to selectively form the crystal defects that cause the shallow trap level and the crystal defects that cause the deep trap level in the silicon substrate.

In the producing methods of the first to third examples, it is preferable that the total number of the crystal defects that cause a trap level that differs from the energy level of the center of the band gap by less than 0.2 eV, be made greater than the number of the crystal defects that cause the trap level that is the second closest to the energy level of the center of the band gap among the trap levels that differ from the energy level of the center of the band gap by 0.2 eV or more. Specifically, it is preferable that in the semiconductor device, the above expression (3) be satisfied. When a large number of the crystal defects formed in the silicon substrate are terminated, it is possible that the life-time control function is not maintained. When the expression (3) is satisfied in the semiconductor device, however, it is possible to secure a sufficient number of crystal defects to maintain the life-time control function. Thus, it is possible to reduce the leakage current and at the same time it is ensured that the life-time control function is maintained.

While the examples of the invention have been described in detail above, these are merely examples and the scope of claims is not limited to these examples. The technology described in the claims includes various modifications and alterations of the specific examples illustrated above. For example, although the diode and the producing method thereof are described in the description of The examples, the semiconductor device and the producing method thereof may be another semiconductor device, such as a metal oxide semiconductor (MOS) or an insulated-gate bipolar transistor (IGBT), and the producing method thereof. The technical features described in the specification and the drawings exhibit a technical utility alone or in various combinations and the combination is not limited to those of the examples described in the specification at the time of filing. In addition, the technology illustrated in the specification and the drawings achieves multiple objects simultaneously and is technically useful when whichever one of the objects is achieved.

1. A method of producing a semiconductor device, in which a plurality of crystal defects for controlling life time of carries are distributed in a silicon substrate, the method comprising:
a crystal defect forming step of forming the plurality of crystal defects in the silicon substrate; and
a termination step of performing termination of the plurality of crystal defects to make a total number of the crystal defects that cause a trap level . that differs from an energy level of a center of a band gap by less than 0.2 eV, less than a number of the crystal defects that cause a trap level that is the closest to the energy level of the center of the band gap among the trap levels that differ from the energy level of the center of the band gap by 0.2 eV or more, wherein the termination step includes:
an implanting step of implanting hydrogen ions into the silicon substrate; and
a heat treatment step of heat-treating the silicon substrate, and wherein the total number of the crystal defects that cause the trap level that differs from the energy level of the center of the band gap by less than 0.2 eV is made greater than a number of the crystal defects that cause a trap level that is the second closest to the energy level of the center of the band gap among the trap levels that differ from the energy level of the center of the band gap by 0.2 eV or more.

2. (canceled)

3. A semiconductor device comprising a silicon substrate having a plurality of crystal defects for controlling life time of carries,
wherein a total number of the crystal defects that cause a trap level that differs from an energy level of a center of a band gap by less than 0.2 eV, is less than a number of the crystal defects that cause a trap level that is the closest to the energy level of the center of the band gap among trap levels that differ from the energy level of the center of the band gap by 0.2 eV or more, and
wherein the total number of the crystal defects that cause the trap level that differs from the energy level of the center of the band gap by less than 0.2 eV is greater than a number of the crystal defects that cause a trap level that is the second closest to the energy level of the center of the band gap among the trap levels that differ from the energy level of the center of the band gap by 0.2 eV or more.

4. (canceled)

5. The method of producing a semiconductor device according to claim 1, wherein,
In the implanting step, an acceleration energy is 4 MeV or 8 MeV and an amount of irradiation is 6×10¹² cm⁻², and,
In the heat treatment step, an atmosphere is a nitrogen atmosphere or a hydrogen atmosphere, a heating temperature is 400° C., and a heat treatment time is 30 minutes.
